(19) United States
(12) Patent Application Publication
(10) Pub. No.: US 2024/0364327 A1
(43) Pub. Date: Oct. 31, 2024

(54) DRIVING CIRCUIT, MICROFLUIDIC DRIVING DEVICE AND DRIVING METHOD

(71) Applicant: Shanghai Tianma Micro-electronics Co., Ltd., Shanghai (CN)

(72) Inventors: Kaidi ZHANG, Shanghai (CN); Baiquan LIN, Shanghai (CN); Wei LI, Shanghai (CN); Dongli ZHANG, Shanghai (CN); Linzhi WANG, Shanghai (CN); Haotian LU, Shanghai (CN); Kerui XI, Shanghai (CN)

(21) Appl. No.: 18/405,719

(22) Filed: Jan. 5, 2024

(30) Foreign Application Priority Data
Apr. 28, 2023 (CN) 202310486734.4

(51) Int. Cl. H03K 17/56; H03K 19/20

(52) U.S. Cl. CPC H03K 17/56; H03K 19/20

(57) ABSTRACT

Driving circuit, microfluidic driving device and driving method are provided. The driving circuit includes a data writing module, a first inverter and a second inverter. An output terminal of the data writing module is connected to a first node. A first terminal of the first inverter is connected to a first power supply terminal, a second terminal of the first inverter is connected to a second power supply terminal, an input terminal of the first inverter is connected to the first node, and an output terminal of the first inverter is connected to a second node. A first terminal of the second inverter is connected to the first power supply terminal, a second terminal of the second inverter is connected to the second power supply terminal, and an input terminal of the second inverter is connected to the second node.

### CROSS-REFERENCE TO RELATED APPLICATION

This application claims priority of Chinese Patent Application No. 202310486734.4, filed on Apr. 28, 2023, the entire contents of which are hereby incorporated by reference.

### FIELD OF THE DISCLOSURE

The present disclosure generally relates to the field of display technology and, more particularly, relates to a driving circuit, a microfluidic driving device and a driving method.

### BACKGROUND

Micro fluidics technology is an emerging interdisciplinary subject involving chemistry, fluid physics, microelectronics, new materials, biology, and biomedical engineering. The technology enables precise control of droplet movements and realizes fusions and separations of droplets and complete various biochemical reactions. The technology is mainly characterized by manipulating fluids in a micron-scale space. Microfluidic chips have advantages of small size, low power consumption, low cost, and less samples and reagents required, which can realize individual and precise control of droplets, short detection time, high sensitivity, and easy integration with other devices. Microfluidic chips are widely used in biology, chemistry, medicine, and other fields.

A driving circuit is usually used to drive droplets, and relies on a storage capacitor for signal retention, making the driving circuit difficult to achieve rapid signal writing and drive a large-scale array of droplets.

### BRIEF SUMMARY OF THE DISCLOSURE

One aspect of the present disclosure provides a driving circuit. The driving circuit includes a data writing module, a first inverter and a second inverter. An output terminal of the data writing module is connected to a first node. A first terminal of the first inverter is connected to a first power supply terminal, a second terminal of the first inverter is connected to a second power supply terminal, an input terminal of the first inverter is connected to the first node, and an output terminal of the first inverter is connected to a second node. A first terminal of the second inverter is connected to the first power supply terminal, a second terminal of the second inverter is connected to the second power supply terminal, an input terminal of the second inverter is connected to the second node, and an output terminal of the second inverter is connected to the input terminal of the first inverter.

Another aspect of the present disclosure provides a microfluidic driving device. The microfluidic driving device includes a substrate, a driving layer, and a microfluidic structure layer. The driving layer is between the substrate and the microfluidic structure layer. The driving layer includes a driving circuit, a plurality of driving electrodes and a common electrode opposite to the driving electrodes, and an output terminal of the driving circuit is electrically connected to the plurality of driving electrodes. The microfluidic structure layer includes at least one first channel, and the first channel corresponds to the plurality of driving electrodes. The driving circuit includes a data writing module, a first inverter and a second inverter. An output terminal of the data writing module is connected to a first node. A first terminal of the first inverter is connected to a first power supply terminal, a second terminal of the first inverter is connected to a second power supply terminal, an input terminal of the first inverter is connected to the first node, and an output terminal of the first inverter is connected to a second node. A first terminal of the second inverter is connected to the first power supply terminal, a second terminal of the second inverter is connected to the second power supply terminal, an input terminal of the second inverter is connected to the second node, and an output terminal of the second inverter is connected to the input terminal of the first inverter.

Another aspect of the present disclosure provides a driving method of a microfluidic driving device. The microfluidic driving device includes a substrate, a driving layer, and a microfluidic structure layer. The driving layer is between the substrate and the microfluidic structure layer. The driving layer includes a driving circuit, a plurality of driving electrodes and a common electrode opposite to the driving electrodes, and an output terminal of the driving circuit is electrically connected to the plurality of driving electrodes. The microfluidic structure layer includes at least one first channel, and the first channel corresponds to the plurality of driving electrodes. The driving circuit includes a data writing module, a first inverter and a second inverter. An output terminal of the data writing module is connected to a first node. A first terminal of the first inverter is connected to a first power supply terminal, a second terminal of the first inverter is connected to a second power supply terminal, an input terminal of the first inverter is connected to the first node, and an output terminal of the first inverter is connected to a second node. A first terminal of the second inverter is connected to the first power supply terminal, a second terminal of the second inverter is connected to the second power supply terminal, an input terminal of the second inverter is connected to the second node, and an output terminal of the second inverter is connected to the input terminal of the first inverter. The driving method includes: introducing a droplet into a first channel; in a first stage, providing a first control signal to the driving circuit connected to a driving electrode at a position of the droplet, controlling the data writing module to be turned on, the data signal line inputting a first signal, and controlling the microfluidic circuit to transmit a driving signal to the driving electrode; and in a second stage, providing a second control signal to the driving circuit, controlling the data writing module to be turned off, and the first inverter and the second inverter controlling the driving circuit to transmit a driving holding signal to the driving electrode by controlling signals at the first node and the second node.

Other aspects of the present disclosure can be understood by a person skilled in the art in light of the description, the claims, and the drawings of the present disclosure.

### BRIEF DESCRIPTION OF THE DRAWINGS

Accompanying drawings, which are incorporated into and constitute a part of the present specification, illustrate embodiments of the present disclosure and together with the description, serve to explain principles of the present disclosure.

FIG. 1 illustrates a schematic diagram of a microfluidic driving circuit;

FIG. 2 illustrates a schematic diagram of a driving circuit consistent with various embodiments of the present disclosure;

FIG. 3 illustrates a connection diagram of a driving circuit and a driving electrode consistent with various embodiments of the present disclosure;

FIG. 4 illustrates another connection diagram of a driving circuit and a driving electrode consistent with various embodiments of the present disclosure;

FIG. 5 illustrates a circuit diagram of a driving circuit consistent with various embodiments of the present disclosure;

FIG. 6 illustrates another circuit diagram of a driving circuit consistent with various embodiments of the present disclosure;

FIG. 7 illustrates another schematic diagram of a driving circuit consistent with various embodiments of the present disclosure;

FIG. 8 illustrates a circuit diagram of a driving circuit including a gating module;

FIG. 9 illustrates another circuit diagram of a driving circuit including a gating module;

FIG. 10 illustrates a schematic diagram of a microfluidic driving device consistent with various embodiments of the present disclosure;

FIG. 11 illustrates a top view of an area where a driving circuit is in a microfluidic drive consistent with various embodiments of the present disclosure;

FIG. 12 illustrates a cross-sectional view of AA′ of the microfluidic driving device in FIG. 11;

FIG. 13 illustrates another top view of an area where a driving circuit is in a microfluidic drive consistent with various embodiments of the present disclosure;

FIG. 14 illustrates a cross-sectional view of BB′ of the microfluidic driving device in FIG. 13;

FIG. 15 illustrates another cross-sectional view of AA′ of the microfluidic driving device in FIG. 11;

FIG. 16 illustrates a flow chart of a driving method for a microfluidic driving device consistent with various embodiments of the present disclosure;

FIG. 17 illustrates a timing diagram corresponding to the driving circuit in FIG. 5;

FIG. 18 illustrates a timing diagram corresponding to the driving circuit in FIG. 6;

FIG. 19 illustrates a timing diagram corresponding to the driving circuit in FIG. 8;

FIG. 20 illustrates a schematic diagram of another driving circuit consistent with various embodiments of the present disclosure;

FIG. 21 illustrates a schematic diagram of another driving circuit including a gating module consistent with various embodiments of the present disclosure;

FIG. 22 illustrates another flow chart of a driving method of a microfluidic driving device consistent with various embodiments of the present disclosure;

FIG. 23 illustrates a timing diagram corresponding to the driving circuit in FIG. 20;

FIG. 24 illustrates a flow chart of another driving method of a microfluidic driving device consistent with various embodiments of the present disclosure; and

FIG. 25 illustrates a timing diagram corresponding to the driving circuit in FIG. 24.

### DETAILED DESCRIPTION

Various exemplary embodiments of the present disclosure will be described in detail with reference to the accompanying drawings. It should be noted that, unless specifically stated otherwise, a relative arrangement of components and steps, numerical expressions and numerical values set forth in the embodiments do not limit the scope of the present disclosure.

The following description of at least one exemplary embodiment is merely illustrative and is not intended to limit the present disclosure and application or use thereof.

Techniques, methods, and apparatus known to a person skilled in the art may not be discussed in detail, but where appropriate, such techniques, methods, and apparatus should be considered as part of the present specification.

In all examples shown and discussed herein, any specific value should be construed as illustrative only and not as a limitation. Accordingly, other examples of exemplary embodiments may have different values.

It will be apparent to a person skilled in the art that various modifications and variations can be made in the present disclosure without departing from the spirit or scope of the present disclosure. Accordingly, the present disclosure is intended to cover the modifications and variations of the present disclosure that fall within the scope of corresponding claims (claimed technical solutions) and equivalents thereof. It should be noted that, implementations provided in the embodiments of the present disclosure may be combined with each other if there is no contradiction.

It should be noted that similar numerals and letters refer to similar items in the following accompanying drawings. Once an item is defined in one accompanying drawing, the item does not require further discussion in subsequent accompanying drawings.

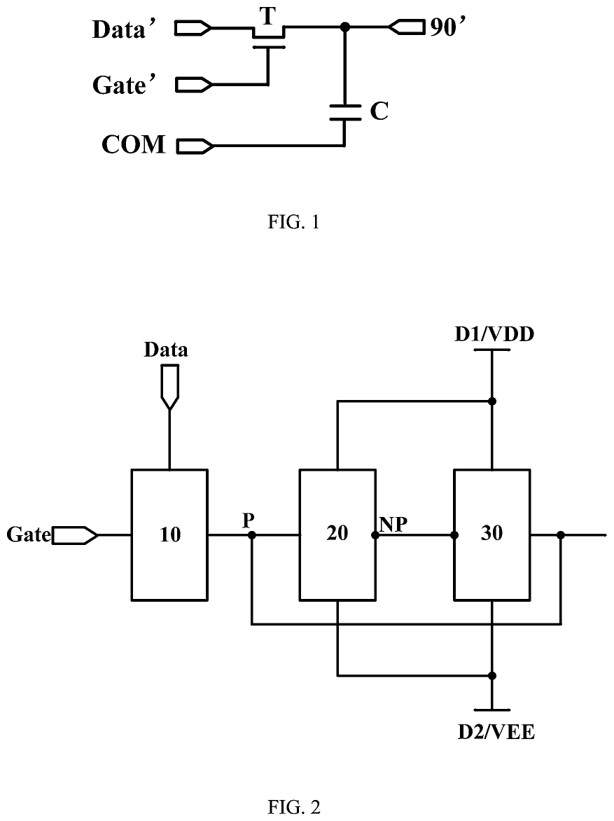

FIG. 1 illustrates a schematic diagram of a microfluidic driving circuit. The microfluidic driving circuit is used to provide a driving voltage to a driving electrode in the microfluidic driving device to drive a liquid droplet in the microfluidic driving device to move. The driving circuit includes a transistor T and a storage capacitor C. A first pole of the transistor T is connected to a data line Data′, a second pole of the transistor T is connected to a driving electrode 90′, and a gate of the transistor T is connected to a control line Gate′. One pole of the storage capacitor C is connected to a common signal line COM, and the other pole is connected to the driving electrode 90′.

When the transistor is turned on, a data signal on the data line is transmitted to the driving electrode and the storage capacitor, so that the driving electrode generates a driving voltage to drive the droplet forward. When the transistor is turned off, the voltage stored in the storage capacitor is applied to the driving electrode, so that the driving electrode has a certain holding voltage to further drive the droplet to move. Therefore, the driving circuit in a related art relies on the storage capacitor for signal retention, making the driving circuit difficult to achieve rapid signal writing and drive a large-scale array of droplets.

Therefore, the present disclosure provides a driving circuit, including a data writing module, a first inverter and a second inverter. An output terminal of the data writing module is connected to a first node. A first terminal of the first inverter is connected to a first power supply terminal, a second terminal of the first inverter is connected to a second power supply terminal, an input terminal of the first inverter is connected to the first node, and an output terminal of the first inverter is connected to a second node. A first terminal of the second inverter is connected to the first power supply terminal, a second terminal of the second inverter is connected to the second power supply terminal, an input terminal of the second inverter is connected to the second node, and an output terminal of the second inverter is connected to the input terminal of the first inverter. Therefore, a fast writing of a driving signal can be realized without introducing a storage capacitor, which is beneficial to realize a driving of a large-scale array.

The above is a core idea of the present disclosure, and technical solutions in the embodiments of the present disclosure will be clearly and completely described below in conjunction with the accompanying drawings in the embodiments of the present disclosure. Based on the embodiments of the present disclosure, all other embodiments obtained by a person skilled in the art without making creative efforts belong to the protection scope of the embodiments of the present disclosure.

FIG. 2 illustrates a schematic diagram of a driving circuit consistent with various embodiments of the present disclosure. In one embodiment, the driving circuit includes a data writing module 10, a first inverter 20 and a second inverter 30. An output terminal of the data writing module 10 is connected to a first node P, a first terminal of the first inverter 20 is connected to a first power supply terminal D1, a second terminal of the first inverter 20 is connected to a second power supply terminal D2, an input terminal of the first inverter 20 is connected to the first node P, and an output terminal of the first inverter 20 is connected to the second node NP. A first terminal of the second inverter 30 is connected to the first power supply terminal D1, a second terminal of the second inverter 30 is connected to the second power supply terminal D2, an input terminal of the second inverter 30 is connected to the second node NP, and an output terminal of the second inverter 30 is connected to the input terminal of the first inverter 20, that is, the first node P.

It should be noted that all the data writing module 10, the first inverter 20 and the second inverter 30 described in the embodiments of the present disclosure do not include a capacitor.

In the embodiment, in the driving circuit, the data writing module 10 and two inverters are introduced. The output terminal of the data writing module 10, the input terminal of the first inverter 20 and the output terminal of the second inverter 30 are all connected to the first node P. The output terminal of the first inverter 20 and the input terminal of the second inverter 30 are connected to the second node NP, and the two inverters form a latch circuit. When the data writing module 10 is turned on, the data writing module 10 writes data into the output terminal of the second inverter 30, and the output terminal of the second inverter 30 can be used as an output terminal of the driving circuit. A signal can be directly provided to the driving electrode to be driven through the output terminal of the second inverter 30, without introducing a storage capacitor and a charging process for the storage capacitor, so that fast writing of the signal can be realized. After the data writing module 10 is turned off, the signal on the output terminal of the second inverter 30 is fed back to the input terminal of the first inverter 20, and the signal controlling the first power supply terminal D1 or the second power supply terminal D2 is transmitted to the output terminal of the driving circuit through the second inverter 30 as a driving holding signal. Or the output terminal of the driving circuit is controlled to output the driving holding signal, to realize feedback locking of the signal, which is conducive to realizing a long-term holding of the driving signal. Therefore, in the embodiment, the driving circuit eliminates a need for a storage capacitor, enabling fast writing and long-term holding of the signals, which is conducive to realizing driving a large-scale driving electrode 90 array, and improving a driving efficiency of droplets. An application of the driving circuit to a microfluidic driving device is conducive to improving the driving efficiency of droplets.

Referring to FIG. 2, in one optional embodiment, the driving circuit is configured to provide a driving signal to the driving electrode in the microfluidic driving device. The output terminal of the second inverter 30 is configured as the output terminal of the driving circuit and is electrically connected to the driving electrode, or signals at the first node P and the second node NP are configured as control signals to control an output of a signal on the output terminal of the driving circuit.

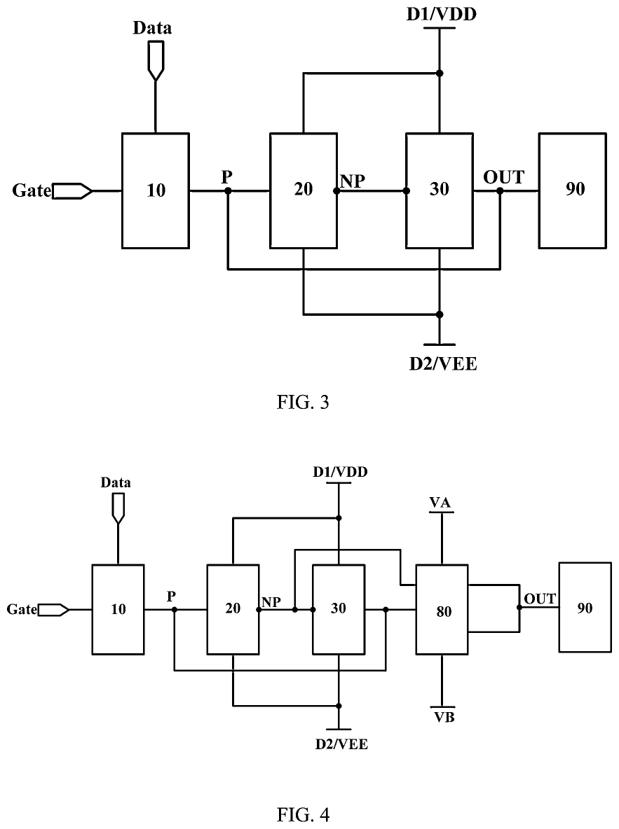

Specifically, in the embodiment, when the driving circuit is applied to a microfluidic driving device, the driving circuit can be configured to provide a driving signal to the driving electrode in the microfluidic driving device. In a first implementation, the output terminal of the second inverter 30 serves as the output terminal of the driving circuit. For example, referring to FIG. 3, the output terminal of the second inverter 30 is electrically connected to the driving electrode 90 in the microfluidic driving device. Therefore, when the data writing module 10 is turned on, a data signal provided by the data writing module 10 can be directly provided to the driving electrode 90 as a driving signal, thereby effectively improving a driving efficiency of the driving electrode 90. FIG. 3 illustrates a connection diagram of a driving circuit and a driving electrode consistent with various embodiments of the present disclosure. In a second implementation, referring to FIG. 4, signals at the first node P and the second node NP are configured as control signals to control the output of the signal on the output terminal of the driving circuit. FIG. 4 illustrates another connection diagram of a driving circuit and a driving electrode consistent with various embodiments of the present disclosure. In one embodiment, a gating module 80 is introduced into the driving circuit, an output of the gating module 80 is controlled by the signals of the first node P and the second node NP. A signal output by the gating module 80 is provided to the driving electrode 90 as a driving signal. The second implementation also does not need to introduce a storage capacitor into the driving circuit, which is also conducive to improving the driving efficiency of the driving electrode 90 and realizing driving of a large-scale array of driving electrodes 90. A specific composition of the gating module 80 will be described in detail in subsequent embodiments.

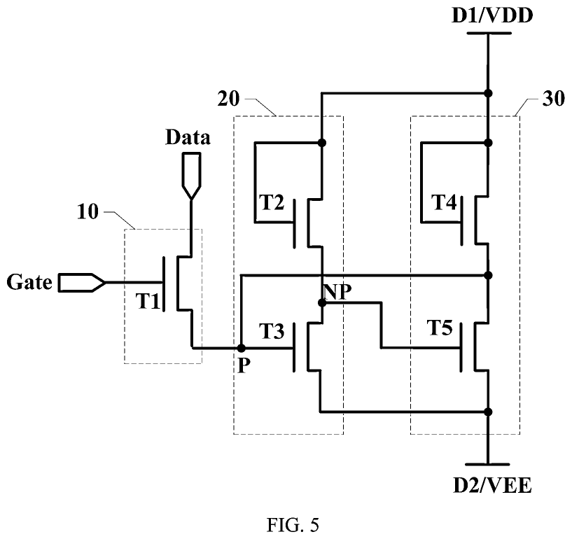

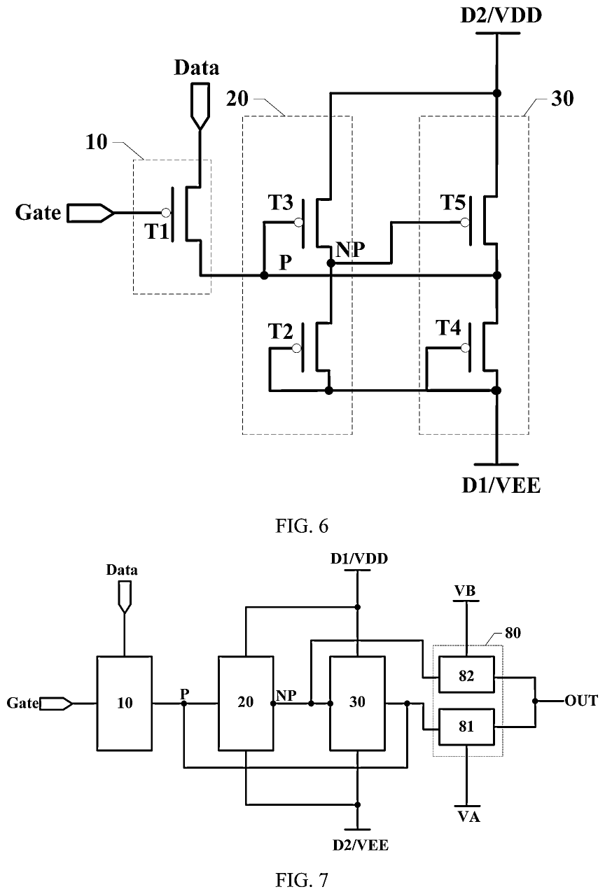

FIG. 5 and FIG. 6 respectively illustrate a circuit diagram of a driving circuit consistent with various embodiments of the present disclosure. In one embodiment, a composition of the data writing module 10, the first inverter 20 and the second inverter 30 in the driving circuit is refined.

Referring to FIG. 5 and FIG. 6, in one optional embodiment, the data writing module 10, the first inverter 20 and the second inverter 30 all include transistors of a same type.

Specifically, the embodiment shows a scheme in which the data writing module 10, the first inverter 20 and the second inverter 30 are all composed of transistors. When the data writing module 10, the first inverter 20 and the second inverter 30 are all composed of transistors, types of all the transistors are same. For example, referring to FIG. 5, each transistor may be embodied as an N-type transistor, or referring to FIG. 6, each transistor may be embodied as a P-type transistor. Therefore, transistors with a same structure can be used to form the driving circuit, eliminating a need for different transistor structures, which is conducive to reducing a process complexity involved in forming the driving circuit and improving a production efficiency.

When the above transistors are all embodied as N-type transistors, if a high-level signal is applied to a control terminal of an N-type transistor, and a corresponding transistor is turned on. Conversely, if a low-level signal is applied to the control terminal of the N-type transistor, a corresponding transistor is turned off. When the above transistors are all embodied as P-type transistors, if a low-level signal is applied to a control terminal of a P-type transistor, a corresponding transistor is turned on. Conversely, if a high-level signal is applied to the control terminal of the P-type transistor, a corresponding transistor is turned off.

Referring to FIG. 5 and FIG. 6, in one optional embodiment, the data writing module 10 includes a first transistor T1. A gate of the first transistor T1 is connected to a control signal line Gate, a first pole of the first transistor T1 is connected to the data signal line Data, and a second pole of the first transistor T1 is connected to the first node P. When a control signal is provided to the gate of the first transistor T1 through the control signal line Gate, the first transistor T1 can be controlled to be turned on or off. In one embodiment shown in FIG. 5, the first transistor T1 is taken as an illustrative example of an N-type transistor. When the control signal line Gate provides a high-level signal to the gate of the first transistor T1, the first transistor T1 is turned on, and a signal on the data signal line Data is transmitted to the first node P. When the control signal line Gate provides a low-level signal to the gate of the first transistor T1, the first transistor T1 is turned off.

In the embodiment shown in FIG. 6, the first transistor T1 is taken as a P-type transistor as an example for illustration. When the control signal line Gate provides a low-level signal to the gate of the first transistor T1, the first transistor T1 is turned on, and the signal on the data signal line Data is transmitted to the first node P. When the control signal line Gate provides a high-level signal to the gate of the first transistor T1, the first transistor T1 is turned off.

Referring to FIG. 5 and FIG. 6, in one optional embodiment, the first inverter 20 includes a second transistor T2 and a third transistor T3, a gate and a first pole of the second transistor T2 are both connected to the first power supply terminal D1, and a second pole of the second transistor T2 is connected to the second node NP. A gate of the third transistor T3 is connected to the first node P, a first pole of the third transistor T3 is connected to the second power supply terminal D2, and a second pole of the third transistor T3 is connected to the second node NP.

Specifically, the embodiment shows a scheme in which the first inverter 20 includes two transistors: the second transistor T2 and the third transistor T3. The second transistor T2 and the third transistor T3 are connected in series between the first power supply terminal D1 and the second power supply terminal D2. The gate and the first pole of the second transistor T2 are connected to the first power supply terminal D1, the gate of the third transistor T3 is connected to the first node P. That is, the third transistor T3 is turned on or off under a control of a potential of the first node P. The third transistor T3 in the embodiment shown in FIG. 5 is an N-type transistor. When the potential of the first node P is a high potential, if the third transistor T3 is controlled to be turned on, a signal on the second power supply terminal D2 transmitted by the third transistor T3 is used as an output signal on the first inverter 20. When the potential of the first node P is a low potential, when the third transistor T3 is controlled to be cut off, the second transistor T2 will be turned on, and a signal on the first power supply terminal D1 transmitted by the second transistor T2 is used as the output signal on the first inverter 20. The third transistor T3 in the embodiment shown in FIG. 6 is a P-type transistor. When a potential of the first node P is a low potential, the third transistor T3 is controlled to be turned on, and a signal on the second power supply terminal D2 transmitted by the third transistor T3 is used as the output signal on the first inverter 20. When the potential of the first node P is a high potential, when the third transistor T3 is controlled to be cut off, the second transistor T2 is turned on, and a signal on the first power terminal D1 transmitted by the second transistor T2 is used as the output signal on the first inverter 20.

Optionally, referring to FIG. 5, when the transistors in the driving circuit are N-type transistors, a signal on the first power supply terminal D1 is a first power supply signal with a voltage value of VDD, and a signal on the second power supply terminal D2 is a second power supply signal with a voltage value of VEE. Referring to FIG. 6, when the transistors in the driving circuit are P-type transistors, the signal on the first power supply terminal D1 is a second power supply signal with a voltage value of VEE, and the signal on the second power supply terminal D2 is the first power supply signal with a voltage value of VDD.

In one optional embodiment, in the first inverter 20, a width-to-length ratio of the second transistor T2 is A2, a width-to-length ratio of the third transistor T3 is A3, A3=k1*A2, and k1≥10. That is, in the first inverter 20, the width-to-length ratio of the third transistor T3 is much larger than the width-to-length ratio of the second transistor T2. Therefore, when the third transistor T3 is turned on, since A3 is much greater than A2, an impedance of the second transistor T2 is much greater than an impedance of the third transistor T3, which can ensure that the second transistor T2 is in a turning-off state. When the third transistor T3 is turned off, the impedance of the second transistor T2 is much smaller than the impedance of the third transistor T3, so that the second transistor T2 can be ensured to be in a turning-on state, which is conducive to ensuring that a performance of the first inverter 20 is more reliable.

Referring to FIG. 5 and FIG. 6, in one optional embodiment, the second inverter 30 includes a fourth transistor T4 and a fifth transistor T5. A gate and a first pole of the fourth transistor T4 are both connected to the first power supply terminal D1, and a second pole of the fourth transistor T4 is connected to the first node P. A gate of the fifth transistor T5 is connected to the second node NP, a first pole of the fifth transistor T5 is connected to the second power supply terminal D2, and a second pole of the fifth transistor T5 is connected to the first node P.

Specifically, the embodiment shows a scheme in which the first inverter 20 includes two transistors: the fourth transistor T4 and the fifth transistor T5. The fourth transistor T4 and the fifth transistor T5 are connected in series between the first power supply terminal D1 and the second power supply terminal D2, the gate and first pole of the fourth transistor T4 are connected to the first power supply terminal D1, and the gate of the fifth transistor T5 pole is connected to the second node NP. That is, the fifth transistor T5 is turned on or off under a control of a potential of the second node NP. The fifth transistor T3 in the embodiment shown in FIG. 5 is an N-type transistor. When the potential of the second node NP is a high potential, if the fifth transistor T5 is controlled to be turned on, a signal on the second power supply terminal D2 transmitted by the fifth transistor T5 signal is used as an output signal on the second inverter 30. When the potential of the second node NP is low and the fifth transistor T5 is turned off, the fourth transistor T4 is turned on, and the signal on the first power terminal D1 transmitted by the fourth transistor T4 is used as the output signal on the second inverter 30. The fifth transistor T3 in the embodiment shown in FIG. 6 is a P-type transistor. When the potential of the second node NP is a low potential, if the fifth transistor T5 is controlled to be turned on, a signal on the second power supply terminal D2 transmitted by the fifth transistor T5 signal is used as the output signal on the second inverter 30. When the potential of the second node NP is a high potential, if the fifth transistor T5 is controlled to be turned off, the fourth transistor T4 is turned on, and the signal on the first power terminal D1 transmitted by the fourth transistor T4 is used as the output signal on the second inverter 30.

In one optional embodiment, in the second inverter 30, a width-to-length ratio of the fourth transistor T4 is A4, a width-to-length ratio of the fifth transistor T5 is A5, A5=k3*A4, and k3≥10. That is, in the second inverter 30, the width-to-length ratio of the fifth transistor T5 is much larger than the width-to-length ratio of the fourth transistor T4. Therefore, when the fifth transistor T5 is turned on, since A5 is much greater than A4, an impedance of the fourth transistor T4 is much greater than an impedance of the fifth transistor T5, thereby ensuring that the fourth transistor T4 is in a turning-off state; when the fifth transistor T5 is turned off, the impedance of the fourth transistor T4 is much smaller than the impedance of the fifth transistor T5, thereby ensuring that the fourth transistor T4 is in a turning-on state, which is conducive to ensuring that a performance of the second inverter 30 is more reliable.

Optionally, the width-to-length ratio A2 of the second transistor T2 in the first inverter 20 is equal to the width-to-length ratio A4 of the fourth transistor T4 in the second inverter 30, and the width-to-length ratio A3 of the third transistor T3 in the first inverter 20 is equal to the width-to-length ratio A5 of the fifth transistor T5 in the second inverter 30. Therefore, in a process of forming the driving circuit, the second transistor T2 and the fourth transistor T4 can be formed with same specifications and the third transistor T3 and the fifth transistor T5 can be formed with same specifications without introducing different specifications for different transistors, which is conducive to simplifying an overall design of the driving circuit.

Referring to FIG. 5, in one optional embodiment, the transistors are all N-type transistors, the first power supply terminal D1 is a positive power supply terminal, and the second power supply terminal D2 is a negative power supply terminal.

Referring to FIG. 5, when the transistors are all N-type transistors, the N-type transistors are turned on under a control of a high-level signal. When the first power supply terminal D1 is a positive power supply terminal, the gates of the second transistor T2 and the fourth transistor T4 are both connected to the positive power supply terminal. When the first transistor T1 is turned on, assuming that a signal input by the data signal line Data is a high-level signal with a voltage value of Vdata, the high-level signal can be used as the output signal on the driving circuit, T3 is turned on, a signal on the negative power supply terminal is transmitted to the second node NP, the fifth transistor T5 is turned off, the fourth transistor T4 is turned on, and a voltage value of the signal on the output terminal of the driving circuit is VDD−Vth. Vth is a threshold voltage of the fourth transistor T4. Optionally, Vdata=VDD−Vth, which is conducive to ensuring a stability of the output signal on the driving circuit without introducing a storage capacitor, so that fast data writing of the driving circuit to the driving electrode 90 can be realized. When the first transistor T1 is turned off, since a voltage value of the high-level signal at the first node P is VDD-Vth, the second transistor T2 is still in a turning-on state, a signal at the second node NP is still the signal on the negative power supply terminal, and the fifth transistor T5 remains in a turning-off state, a signal on the positive power supply terminal is output to the first node P through the fifth transistor T5, so that the signal the first node P maintains a voltage value of VDD-Vth, which is provided to the driving electrode, thereby realizing a latch function and improving a retention rate of the signal without introducing a storage capacitor. When the first transistor T1 is turned on again, the signal input by the data signal line Data is a low-level signal. When the low-level signal is transmitted to the first node P, the third transistor T3 is turned off, the second transistor T2 is turned on, and the second transistor T2 transmits a high-level signal on the first power supply terminal D1 to the second node NP to control the fifth transistor T5 to be turned on. The fifth transistor T5 transmits the low-level signal on the second power supply terminal D2 to the output terminal of the driving signal. The driving electrode corresponding to the driving circuit does not need to provide a driving signal to drive the droplet forward. Therefore, outputting a low-level signal is conducive to reducing overall power consumption of the driving circuit.

Referring to FIG. 6, in one optional embodiment, the transistors are all P-type transistors, the first power supply terminal D1 is a negative power supply terminal, and the second power supply terminal D2 is a positive power supply terminal.

Referring to FIG. 6, when the transistors are all P-type transistors, the P-type transistors are turned on under a control of a low-level signal. When the first power supply terminal D1 is a negative power supply terminal, the gates of the second transistor T2 and the fourth transistor T4 are connected to the negative power supply terminal. When the first transistor T1 is turned on, assuming that a signal input by the data signal line Data is a high-level signal with a voltage value of Vdata, the high-level signal can be used as the output signal on the driving circuit, the third transistor T3 is turned off, the second transistor T2 is turned on, a signal on the negative power supply terminal is transmitted to the second node NP, the fifth transistor T5 is turned on, the fourth transistor T4 is turned off, a voltage value of the signal on the output terminal of the driving circuit is VDD-Vth and Vth is a threshold voltage of the fifth transistor T5. Optionally, Vdata=VDD−Vth, which is beneficial to ensure the stability of the output signal on the driving circuit. In this stage, there is no need to introduce a storage capacitor, so that the fast data writing of the driving circuit to the driving electrode 90 can be realized. When the first transistor T1 is turned off, since a voltage value of the high-level signal at the first node P is VDD−Vth, the second transistor T2 is still in a turning-on state, the signal at the second node NP is still the signal on the negative power supply terminal, and the fifth transistor T5 remains turned on. The signal on the positive power supply terminal is output to the first node P through the fifth transistor T5, so that the first node P output the signal with a voltage value of VDD−Vth to the driving electrode to realize a latch function and improve the signal retention rate without introducing a storage capacitor. When the first transistor T1 is turned on again, the signal input by the data signal line Data is a low-level signal. When the low-level signal is transmitted to the first node P, the third transistor T3 is turned on, the third transistor T3 transmits the high-level signal on the second power supply terminal D2 to the second node, the fifth transistor T5 is turned off, and the fourth transistor T4 is turned on, and the fourth transistor T4 transmits the low-level signal on the second power supply terminal D2 to the output terminal of the driving signal. The driving electrode corresponding to the driving circuit does not need to provide a driving signal to drive the droplet forward. Therefore, outputting a low-level signal is conducive to reducing overall power consumption of the driving circuit.

FIG. 7 illustrates another schematic diagram of a driving circuit consistent with various embodiments of the present disclosure. One embodiment shows a scheme that the driving circuit further includes a gating module.

Referring to FIG. 7, in one optional embodiment, the driving circuit also includes a gating module 80 including a first gating unit 81 and a second gating unit 82. A control terminal of the first gating unit 81 is connected to the first node P. A control terminal of the second gating unit 82 is connected to the second node NP. A first terminal of the first gating unit 81 is connected to a first level terminal VA, and a second terminal of the first gating unit 81 is connected to the output terminal of the driving circuit. A first terminal of the second gating unit 82 is connected to a second level terminal VB, and a second terminal of the second gating unit 82 is connected to the output terminal of the driving circuit.

Specifically, when the signal at the first node P is a high-level signal, the signal at the second node NP is a low-level signal. When the signal at the first node P is a low-level signal, the signal at the second node NP is a high-level signal. When the signal at the first node P controls the first gating unit 81 to be turned on, the second gating unit 82 is turned off, and a signal on the first level terminal VA is transmitted to the output terminal of the driving circuit. When the signal at the second node NP controls the second gating unit 82 to be turned on, the first gating unit 81 is turned off, and a signal on the second level terminal VB is transmitted to the output terminal of the driving circuit. The signal on the first level terminal VA or the signal the second level terminal VB is used as the output signal on the driving circuit, so that the output of the driving signal is not affected by a fluctuation of transistors in the first inverter 20 and the second inverter 30 and an overall output of the driving circuit is more stable. Assuming that the first node P is a high-level signal, the first gating unit 81 is turned on, and the signal on the first level terminal VA is output from the output terminal of the driving circuit as a driving signal or a driving holding signal provided to the driving electrode. When the signal at the first node P is a low-level signal, the signal at the second node NP is a high-level signal, the second gating unit 82 is turned on, and the signal on the second level terminal VB is transmitted to the output terminal of the driving circuit. Optionally, the signal on the second level terminal VB is a DC signal, such as a 0-level signal. The driving electrode corresponding to the driving circuit does not need to provide a driving signal to drive the droplet forward. Therefore, outputting a low-level signal is beneficial to reduce overall power consumption of the driving circuit.

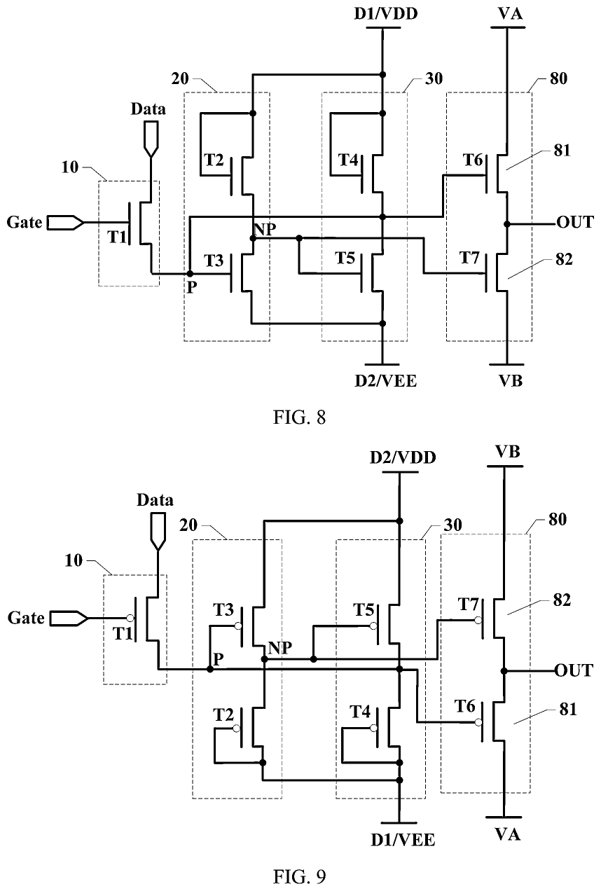

FIG. 8 illustrates a circuit diagram of a driving circuit including a gating module. In one optional embodiment, the first gating unit 81 includes a sixth transistor T6, and the second gating unit 82 includes a seventh transistor T7. Transistors included in the first gating unit 81, the second gating unit 82, the data writing module 10, the first inverter 20 and the second inverter 30 are of a same type.

Specifically, in the embodiment, the first gating unit 81 and the second gating unit 82 respectively include transistors. Types of the transistors are same as types of transistors included in the data writing module 10, the first inverter 20 and the second inverter 30. Therefore, transistors with a same structure can be used to form the driving circuit, eliminating a need for different transistor structures, which is conducive to reducing a process complexity involved in forming the driving circuit and improving a production efficiency.

Referring to FIG. 8, in one optional embodiment, among the first level terminal VA and the second level terminal VB, one transmits an AC signal, and the other transmits a DC signal. A voltage value corresponding to the AC signal is between voltage values of the first power supply terminal D1 and the second power supply terminal D2. Optionally, a voltage of the DC signal may be represented as 0 V. When the gating module 80 is introduced into the driving circuit, the first level terminal VA and the second level terminal VB alternately output signals to the output terminal of the driving circuit. When the signals of the first level terminal VA and the second level terminal VB are respectively an AC signal and a 0V DC signal, the output signal can be switched between the AC signal and the 0V DC signal. When the driving circuit is applied to the microfluidic driving device, AC driving of the droplet can be realized, and a hysteresis effect caused by charge accumulation in the driving process can be reduced.

It should be noted that the embodiment in FIG. 8 is only described by taking each transistor in each driving transistor as an N-type transistor as an example. In other embodiments, when the gating module 80 is introduced into the driving circuit, each transistor can also be embodied as a P-type transistor as shown in FIG. 9. FIG. 9 illustrates another circuit diagram of a driving circuit including a gating module. When the transistors in the driving circuit are P-type transistors as shown in FIG. 9, except that the conduction levels of the transistors are different, a working process of the driving circuit shown in FIG. 9 is similar to a working process of the driving circuit shown in FIG. 8, which is not repeated herein.

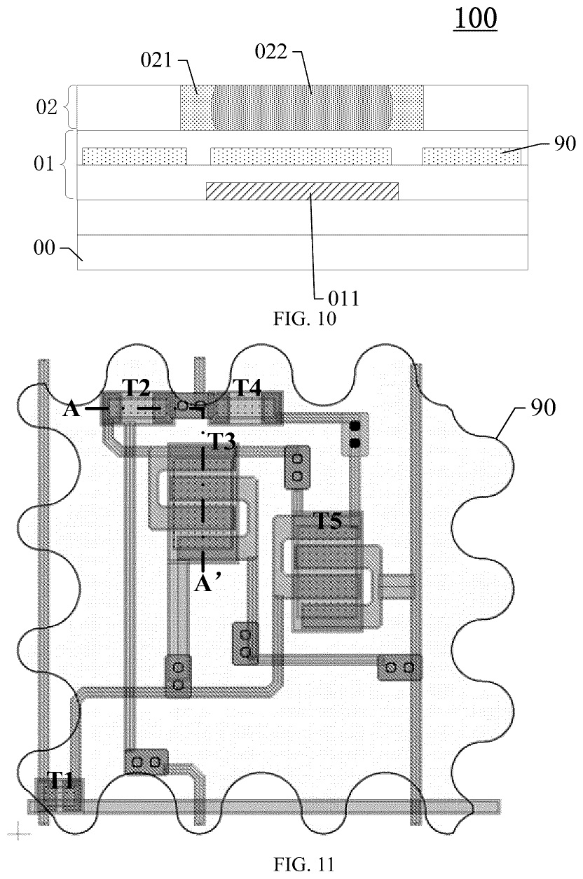

Based on a same inventive concept, the present disclosure also provides a microfluidic driving device. FIG. 10 illustrates a schematic diagram of a microfluidic driving device consistent with various embodiments of the present disclosure. The microfluidic driving device includes a substrate 00, a driving layer 01 and a microfluidic structure layer 02. The driving layer 01 is between the substrate 00 and the microfluidic structure layer 02. The driving layer 01 includes a driving circuit, a plurality of driving electrodes 90 and a common electrode 011 opposite to the plurality of driving electrodes 90. The output terminal of the driving circuit is electrically connected to the plurality of driving electrodes 90. The microfluidic structure layer 02 includes at least one first channel 021 corresponding to the plurality of driving electrodes 90. The driving circuit is the driving circuit described in the above embodiments. Optionally, a liquid droplet 022 are arranged in the first channel 021.

When the driving circuit described in the above embodiments provides driving signals for the driving electrodes 90 in the microfluidic driving device, since there is no need to introduce a storage capacitor in the driving circuit, and there is no need to introduce a charging process for the storage capacitor, the driving signals can be quickly written into the driving electrodes 90 to improve a driving efficiency of droplets. Moreover, a latch circuit composed of the first inverter and the second inverter can also maintain the driving signals for a long time, which is conducive to further improving the driving efficiency of droplets and meeting a driving demand for a large-scale driving electrode array in the microfluidic driving device.

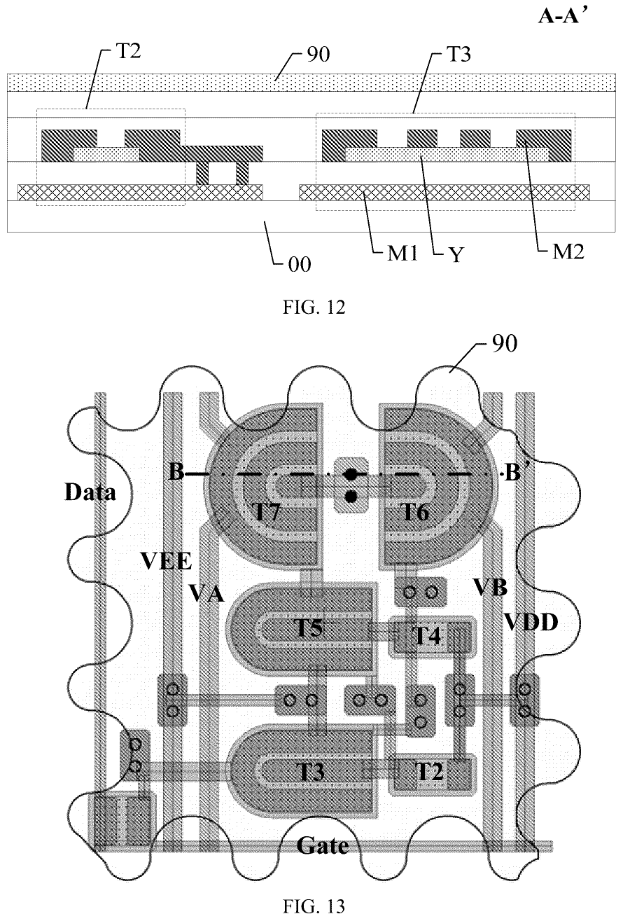

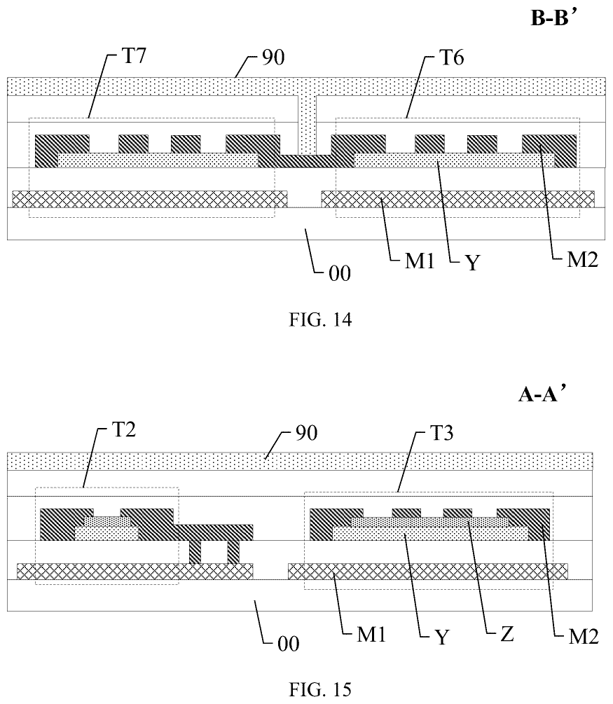

FIG. 11 illustrates a top view of an area where a driving circuit is in a microfluidic drive consistent with various embodiments of the present disclosure. FIG. 12 illustrates a cross-sectional view of AA′ of the microfluidic driving device in FIG. 11. The driving circuit in one embodiment does not include a gating module. FIG. 13 illustrates another top view of an area where a driving circuit is in a microfluidic drive consistent with various embodiments of the present disclosure. FIG. 14 illustrates a cross-sectional view of BB′ of the microfluidic driving device in FIG. 13. The driving circuit in the embodiment includes a gating module.

Referring to FIGS. 11-14, in one optional embodiment, the driving layer includes first metal layers M1, active layers Y, and second metal layers M2 arranged on one side of the substrate 00. The first metal layers M1 are isolated from the active layers Y by an insulating layer, and the first metal layers M1 are between the active layers Y and the substrate 00. The second metal layers M2 are on a side of the active layers Y away from the substrate 00. In the driving circuit, gates of the transistors are on the first metal layers M1, and the first poles and the second poles of the transistors are on the second metal layers M2. An active layer Y include an oxide layer or an amorphous silicon layer.

When the active layers Y are oxide layers, each transistor in the driving circuit is an oxide transistor. When the active layers Y are amorphous silicon layers, each transistor in the driving circuit is a low temperature polysilicon transistor. When oxide transistors or low temperature polysilicon transistors are applied to form the driving circuit of the microfluidic driving device, a structure is relatively simple. When the first metal layer M1 is formed, gates of all the transistors in the driving circuit can be formed in a same process and the active layers Y of all the transistors can also be formed in a same process. When the second metal layer M2 is formed, a source and drain of each transistor can be formed in a same process, which is conducive to simplifying an overall forming process of the microfluidic driving device and improving a production efficiency of the microfluidic driving device.

When the active layers Y are oxide layers, as shown in FIG. 15, an etching stopper layer may further be included between the active layers Y and the second metal layers M2. Etch barrier layers Z can prevent the oxide layers from being etched when the second metal layers M2 are etched, thereby protecting the oxide layers. FIG. 15 illustrates another cross-sectional view of AA′ of the microfluidic driving device in FIG. 11.

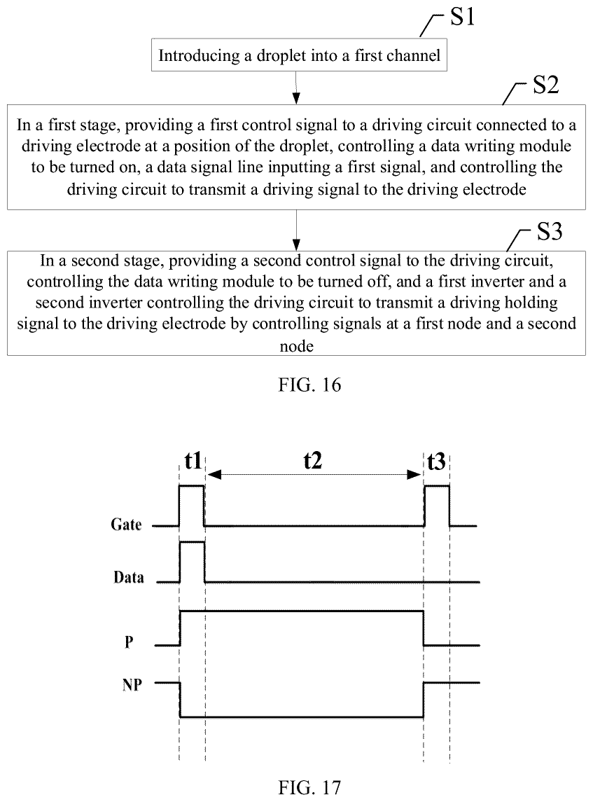

Based on a same inventive concept, the present disclosure also provides a driving method for a microfluidic driving device. FIG. 16 illustrates a flow chart of a driving method for a microfluidic driving device consistent with various embodiments of the present disclosure. The driving method is configured to drive the microfluidic driving device in the above embodiment, and the driving method includes the following steps.

S1: introducing a droplet into a first channel 201.

S2: in a first stage t1, providing a first control signal to the driving circuit connected to a driving electrode 90 at a position of the droplet, controlling the data writing module 10 to be turned on, the data signal line Data inputting a first signal, and controlling the microfluidic circuit to transmit a driving signal to the driving electrode 90.

S3: in a second stage t2, providing a second control signal to the driving circuit, controlling the data writing module 10 to be turned off, and the first inverter 20 and the second inverter 30 controlling the driving circuit to transmit the driving holding signal to the driving electrode 90 by controlling signals of the first node P and the second node NP.

FIG. 17 illustrates a timing diagram corresponding to the driving circuit in FIG. 5. Referring to FIG. 5 and FIG. 17, in the first stage t1, the first control signal is provided to the driving circuit corresponding to the driving electrode 90 at the position of the droplet to turn on the data writing module 10. The first control signal can be regarded as a signal provided to the control terminal of the data writing module 10. The first signal input by the data signal line Data is transmitted to the first node P. When the output terminal of the second inverter 30 is used as the output terminal of the driving circuit, the first signal is used as the output signal on the driving circuit and is output to the driving electrode, and an area where the driving electrode is located generates a driving voltage to drive the droplet forward, thereby realizing fast writing of the driving signal to the driving electrode, which is conducive to realizing effective driving of the droplet.

In the second stage t2, a second control signal is provided to the driving circuit connected to the driving electrode 90 at the position of the droplet, so that the data writing module 10 is turned off. If the output terminal of the second inverter 30 is used as the output terminal of the driving circuit, the latch function of the first inverter 20 and the second inverter 30 can keep the signal at the first node P, so that the driving circuit outputs and continuously provides a driving holding signal to the driving electrode 90.

Referring to FIG. 5 and FIG. 17, in one optional embodiment, the driving method further includes: in a third stage t3, providing the first control signal to the driving circuit, controlling the data writing module 10 to be turned on, the data signal line Data inputting a second signal, controlling the driving circuit to transmit a third signal to the driving electrode 90; and a voltage value corresponding to the third signal being smaller than voltage values of the driving signal and the driving holding signal.

By driving the droplet in the first stage t1 and the second stage t2, the droplet is moved to an edge position of a corresponding n-th driving electrode 90. The n-th driving electrode 90 no longer needs to provide a driving signal to the droplet, and instead a (n+1)-th driving electrode 90 provides a driving signal to the droplet. Therefore, in the third stage t3, when the data writing module 10 is turned on, the second signal can be inputted through the data signal line Data, so that the driving circuit transmits the third signal to the nth driving electrode 90. When the output terminal of the second inverter 30 is used as the output terminal of the driving circuit, the second signal in the third stage t3 is the third signal transmitted to the nth driving electrode 90. A voltage value of the third signal is smaller than voltage values of the driving signal and the driving holding signal, so it is not necessary to drive the nth driving electrode, and the (n+1)-th driving electrode 90 can start to play a drive role, thereby realizing a continuous actuation of droplet.

Referring to FIG. 5 and FIG. 17, in one optional embodiment, in the driving circuit, the data writing module 10 includes a first transistor T1, the first inverter 20 includes a second transistor T2 and a third transistor T3, and the second inverter 30 includes a fourth transistor T4 and a fifth transistor T5. In the first stage t1, the first transistor T1 is turned on, and a voltage value of the driving signal is Vdata1. In the second stage t2, the first transistor T1 is turned off, and the signal output from the first node P is a driving holding signal. The fourth transistor T4 is turned on, and a voltage value of the driving holding signal is VDD−Vth. Vdata1=VDD−Vth, VDD is a voltage value of the first power supply terminal D1, Vth is the threshold voltage of the fourth transistor T4. Alternatively, the fourth transistor T4 is turned on, and the voltage value of the driving holding signal is VEE−Vth. Vdata1=VEE−Vth, VEE is a voltage value of the first power supply terminal D1, and Vth is the threshold voltage of the fourth transistor T4.

Taking the embodiment shown in FIG. 5 and FIG. 17 as an example, each transistor is an N-type transistor. In the first stage t1, a high-level signal is provided to the gate of the first transistor T1, and the first transistor T1 is turned on. Assuming that a signal on the data signal line Data is a high-level driving signal, the signal has a voltage value of Vdata1, and the driving signal is output to the driving electrode 90.

In the second stage t2, a low-level signal is provided to the gate of the first transistor T1, and the first transistor T1 is turned off. The signal at the first node P remains a high-level signal, the third transistor T3 is turned on, and the low-level signal on the second power supply terminal D2 is transmitted to the second node NP, so that the fifth transistor T5 is turned off, and the fourth transistor T4 is turned on. The voltage value of the driving holding signal output by the output terminal of the driving circuit is VDD−Vth, and Vth is the threshold voltage of the fourth transistor T4.

In the embodiment, the voltage value Vdata1 of the driving signal output by the driving circuit in the first stage t1 is set to be equal to the voltage value of VDD−Vth of the driving holding signal output in the second stage t2, so that the voltage values provided to the driving electrodes 90 in the first phase t1 and the second phase t2 are consistent. In the second stage t2, the driving signal is well maintained, which is conducive to realizing effective and continuous driving of the droplet.

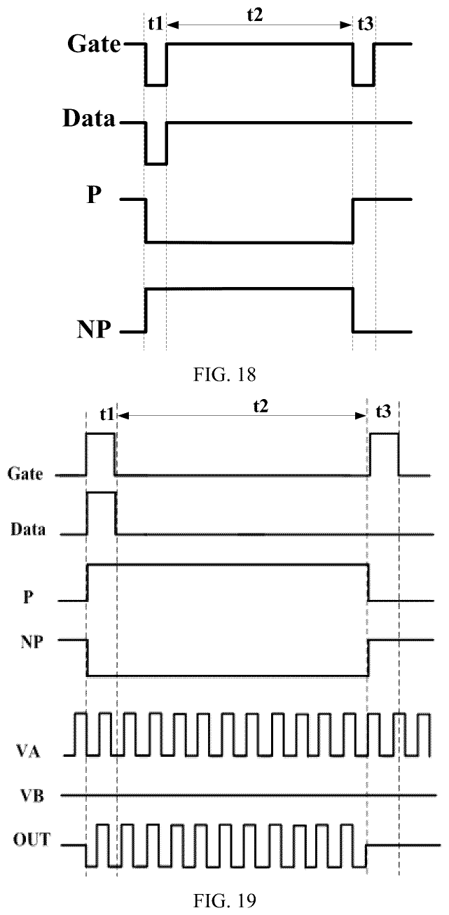

FIG. 18 illustrates a timing diagram corresponding to the driving circuit in FIG. 6. Referring to FIG. 6 and FIG. 18, each transistor is a P-type transistor. In the first stage t1, a low-level signal is provided to the gate of the first transistor T1, and the first transistor T1 is turned on. Assuming that the data signal line Data provides a low-level driving signal with a voltage value of Vdata1, the driving signal is output to the driving electrode. In the second stage t2, a high-level signal is provided to the gate of the first transistor T1, and the first transistor T1 is turned off. The signal at the first node P remains a low-level signal, the third transistor T3 is turned on, and the high-level signal on the second power supply terminal D2 is transmitted to the fifth transistor T5, so that the fifth transistor T5 is turned off, and the fourth transistor T4 is turned on. The voltage value of the driving hold signal output by the output terminal of the driving circuit is VEE−Vth, and Vth is the threshold voltage of the fourth transistor T4. In the embodiment, the voltage value Vdata1 of the driving signal output by the driving circuit in the first stage t1 is set to be equal to the value VED−Vth of the driving holding signal output in the second stage t2, so that the voltage values provided to the driving electrodes 90 in both the first stage t1 and the second stage t2 are consistent. In the second stage t2, the driving signal is well maintained, which is conducive to realizing effective and continuous driving of the droplet.

In one optional embodiment, in the third stage t3, the first transistor T1 is turned on, and the second signal on the data signal line Data is used as the third signal.

In the third stage t3, referring to FIG. 5 and FIG. 17, a high-level signal is provided to the first transistor T1, and the first transistor T1 is turned on. The second signal on the data signal line Data is a low-level signal, which serves as the third signal for driving the driving electrode. In the third stage t3, the droplet leaves the driving electrode, so there is no need to provide a signal that can drive the droplet forward to the driving electrode. The droplet can be driven by a next driving electrode.

FIG. 19 illustrates a timing diagram corresponding to the driving circuit in FIG. 8. In one optional embodiment, in the driving circuit, the data writing module 10 includes the first transistor T1. The first inverter 20 includes the second transistor T2 and the third transistor T3. The second inverter 30 includes the fourth transistor T4 and the fifth transistor T5. The microfluidic circuit also includes the gating module 80 including the sixth transistor T6 and the seventh transistor T7. A first pole of the sixth transistor T6 is connected to the first level terminal VA, and a second pole of the seventh transistor T7 is connected to the second level terminal VB.

In the first stage t1, the first transistor T1 is turned on, the signal at the first node P controls the sixth transistor T6 to be turned on, and the signal on the first level terminal VA is used as a driving signal. In the second stage t2, the first transistor T1 is turned off, the signal at the first node P is maintained, and the sixth transistor T6 is controlled to remain turned on, and the signal on the first level terminal VA is used as a driving holding signal.

Specifically, the embodiment shows a driving method when the driving circuit includes the gating module 80. The embodiment is described by taking each transistor as an N-type transistor as an example. In the first stage t1, the first transistor T1 is turned on, the high-level signal on the data signal line Data is transmitted to the first node P, and the sixth transistor T6 is controlled to be turned on. The seventh transistor T7 is turned off and the signal on the first level terminal VA is used as a driving signal, optionally, the signal on the first level terminal VA is an AC signal.

In the second stage t2, the first transistor T1 is turned off, the signal at the first node P remains a high-level signal, the sixth transistor T6 remains in a turning-on state, and the AC signal on the first level terminal VA continues to serve as a driving holding signal. The driving signal and driving holding signal output by the driving circuit in the first stage t1 and the second stage t2 are consistent AC signals, which is conducive to realizing continuous and stable AC driving of the liquid crystal and reduce hysteresis effect due to charge accumulation during driving.

Referring to FIG. 8 and FIG. 19, in one optional embodiment, In the third stage t3, the first transistor T1 is turned on, the second signal on the data signal line Data is transmitted to the first node P, the second transistor T2 is turned on, the signal on the first power supply terminal D1 is transmitted to the second node NP to control the seventh transistor T7 to be turned on, and the signal on the second level terminal VB is used as the third signal.

Specifically, in the third stage t3, the second signal on the data signal line Data is a low-level signal. When the low-level signal is transmitted to the first node P, the third transistor T3 is turned off, the second transistor T2 is turned on, and the high-level signal on the first level terminal is transmitted to the second node NP, so that the seventh transistor T7 is turned on, and the signal on the second level terminal VB is used as the third signal. Optionally, the signal on the second level terminal VB is a direct current signal, for example, with a voltage value of 0. There is no need to supply the driving electrode 90 with a voltage capable of driving the droplet forward, which is conducive to reducing overall power consumption.

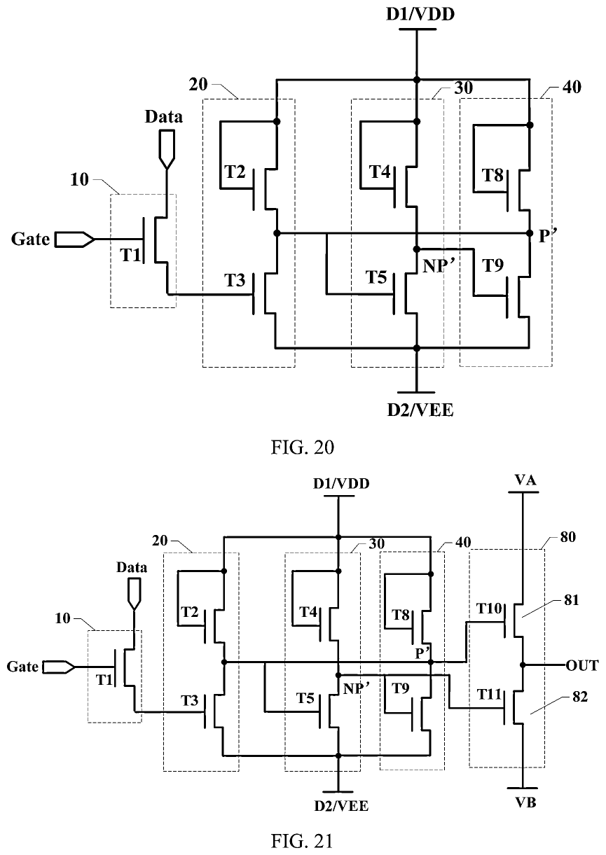

Based on a same inventive concept, the present disclosure also provides another driving circuit. FIG. 20 illustrates a schematic diagram of another driving circuit consistent with various embodiments of the present disclosure. The driving circuit includes the data writing module 10, the first inverter 20, the second inverter 30 and a third inverter 40. The first terminal of the data writing module 10 is connected to the data signal line Data, the second terminal of the data writing module 10 is connected to the input end of the first inverter 20, and the control terminal of the data writing module 10 is connected to the control signal line Gate. The first terminal of the first inverter 20 is connected to the first power supply terminal D1, the second terminal of the first inverter 20 is connected to the second power supply terminal D2, and the output terminal of the first inverter 20 is connected to the third node P′. The first terminal of the second inverter 30 is connected to the first power supply terminal D1, the second terminal of the second inverter 30 is connected to the second power supply terminal D2, the input terminal of the second inverter 30 is connected to the third node P′, and the output terminal of the second inverter 30 is connected to the fourth node NP′. An input terminal of the third inverter 40 is connected to the fourth node NP′, the output terminal is connected to the third node P′, a first terminal of the third inverter 40 is connected to the first power supply terminal D1, and a second terminal of the third inverter 40 is connected to the second power supply terminal D2. The third node P′ is used as the output terminal of the driving circuit and is electrically connected to the driving electrode. Or the third node P′ is used as a control terminal to control an output of the signal on the output terminal of the driving circuit.

Specifically, referring to FIG. 20, in one embodiment, three inverters are introduced into the driving circuit provided, namely, the first inverter 20, the second inverter 30 and the third inverter 40. The output terminal of the first inverter 20, the input terminal of the second inverter 30 and the output terminal of the third inverter 40 are all connected to the third node P′. The output terminal of the second inverter 30 and the input terminals of the third inverter 40 are all connected to the third node P′. When the third node P′ outputs a low-level signal, the fourth node NP′ outputs a high-level signal. When the third node P′ outputs a high-level signal, the fourth node NP′ outputs a low-level signal. Signals at the third node P′ and the fourth node NP′ are stored by a latch. It should be noted that, in the embodiment, the data writing module 10, the first inverter 20, the second inverter 30 and the third inverter 40 do not contain capacitors.

When the third node P′ is used as the output terminal of the driving circuit, after the data writing module 10 is turned on, the signal on the data signal line Data can control the first inverter 20 to transmit the signal on the first power supply terminal D1 to the third node P′, which is conducive to fast writing of the driving signal without introducing a storage capacitor and a charging process for the storage capacitor. After the data writing module 10 is turned off, the signal at the third node P′ is fed back to the input terminal of the second inverter 30 to realize feedback locking of the signal, which is conducive to realizing a long-term maintenance of the driving signal. In addition, in the embodiment, the fourth node NP′ is not connected to the data signal line Data, so the signal at the fourth node NP′ and the signal on the data signal line Data are not prone to crosstalk, which is conducive to improving a stability of the signal output by the driving circuit.

Referring to FIG. 20, the data writing module 10 includes the first transistor T1, the first inverter 20 includes the second transistor T2 and the third transistor T3, the second inverter 30 includes the fourth transistor T4 and the fifth transistor T5, and the third inverter 40 includes an eighth transistor T8 and a ninth transistor T9. The two transistors in the first inverter 20 are connected in series between the first power supply terminal D1 and the second power supply terminal D2, and the two transistors in the second inverter 30 are connected in series between the first power supply terminal D1 and the second power supply terminal D2, and the two transistors in the third inverter 40 are also connected in series between the first power supply terminal D1 and the second power supply terminal D2. The second pole of the third transistor T3, the gate of the fifth transistor T5, and a second pole of the ninth transistor T9 are all connected to the third node P′, and the second pole of the fifth transistor T5 and a gate of the ninth transistor T9 are connected to the fourth node NP′. A specific working process of the driving circuit will be described in detail in the following driving method embodiments. It should be noted that a first pole of a transistor described in the present disclosure usually refers to one pole of the transistor receiving a signal, and a second pole of the transistor generally refers to one pole of the transistor outputting a signal.

FIG. 21 illustrates a schematic diagram of another driving circuit including a gating module consistent with various embodiments of the present disclosure. In one optional embodiment, the driving circuit also includes a gating module 80 including the first gating unit 81 and the second gating unit 82. The control terminal of the first gating unit 81 is connected to the third node P′, the control terminal of the second gating unit 82 is connected to the fourth node NP′, the first terminal of the first gating unit 81 is connected to the first level terminal VA, and the second terminal of the first gating unit 81 is connected to the output terminal OUT of the driving circuit. The first terminal of the second gating unit 82 is connected to the second level terminal VB, and the second terminal of the second gating unit 82 is connected to the output terminal OUT of the driving circuit.

Specifically, when the gating module 80 is introduced into the driving circuit, the output signal at the gating module 80 can be controlled by the signals at the third node P′ and the fourth node NP′, and the output signal on the gating module 80 is provided to the driving electrode 90 as a driving signal. The above solution also does not need to introduce a storage capacitor into the driving circuit, which is also conducive to improving a driving efficiency of the driving electrodes 90 and realizing driving a large-scale driving electrode 90 array.

Optionally, the first gating unit 81 includes a tenth transistor T10, and the second gating unit 82 includes an eleventh transistor T11. A gate of the tenth transistor T10 is connected to the third node P′, and a first pole of the tenth transistor T10 is connected to the first level terminal VA, a second pole of the tenth transistor T10 is connected to the output terminal of the driving circuit. A gate of the eleventh transistor T11 is connected to the fourth node NP′, a first pole of the eleventh transistor T11 is connected to the second power supply terminal D2, and a second pole of the eleventh transistor T11 is connected to the output terminal of the driving circuit. When the signal at the third node P′ controls the tenth transistor T10 to be turned on, the signal on the first level terminal VA is transmitted to the output terminal of the driving circuit as the output signal on the driving circuit. When the signal at the fourth node NP′ controls the eleventh transistor T11 to be turned on, the signal on the second power supply terminal D2 is transmitted to the output terminal of the driving circuit as the output signal on the driving circuit. A specific working sequence of the driving circuit including the gating module 80 will be described in detail in subsequent embodiments.

In one optional embodiment, the data writing module 10, the first inverter 20, the second inverter 30 and the third inverter 40 all include transistors of a same type. For example, each transistor can be embodied as an N-type transistor, or each transistor can be embodied as a P-type transistor. Therefore, transistors with a same structure can be used to form the driving circuit, eliminating a need for different transistor structures, which is conducive to reducing a process complexity involved in forming the driving circuit and improving a production efficiency.

It should be noted that the driving transistors in the driving circuit in the embodiments shown in FIG. 20 and FIG. 21 are taken as N-type transistors as examples for illustration. In some other embodiments, the drive transistors can also be uniformly embodied as P-type transistors, which are not limited herein.

Based on a same inventive concept, the present disclosure also provides another microfluidic driving device. Referring to a structural diagram shown in FIG. 10, the microfluidic driving device includes a substrate 00, a driving layer 01 and a microfluidic structure layer 02. The driving layer 01 is between the substrate 00 and the microfluidic structure layer 02. The driving layer 01 includes a driving circuit, a plurality of driving electrodes 90 and a common electrode 011 opposite to the plurality of driving electrodes 90. The output terminal of the driving circuit is electrically connected to the driving electrodes 90. The microfluidic structure layer includes at least one first channel 021 corresponding to the plurality of driving electrodes 90. The driving circuit is the microfluidic driving circuit of the embodiments shown in FIG. 20 and FIG. 21.

When the driving circuit described in the above embodiments is used to provide the driving signal for the driving electrode 90 in the microfluidic driving device, there is no need to introduce a storage capacitor in the driving circuit, and there is no need to introduce a charging process to the storage capacitor, which allows for fast writing of the driving signal to the driving electrode 90 and improve the driving efficiency of droplets. Moreover, through a latch circuit composed of the first inverter 20, the second inverter 30 and the third inverter 40, a long-term retention of the driving signal can also be realized, which is conducive to further improving the driving efficiency of droplets and meet the driving demand for the large-scale driving electrode 90 array in the microfluidic driving device. In the embodiment, the fourth node NP′ is not connected to the data signal line Data, so the signal at the fourth node NP′ and the signal on the data signal line Data are less prone to crosstalk, which is beneficial to improve the stability of the signal output by the driving circuit.

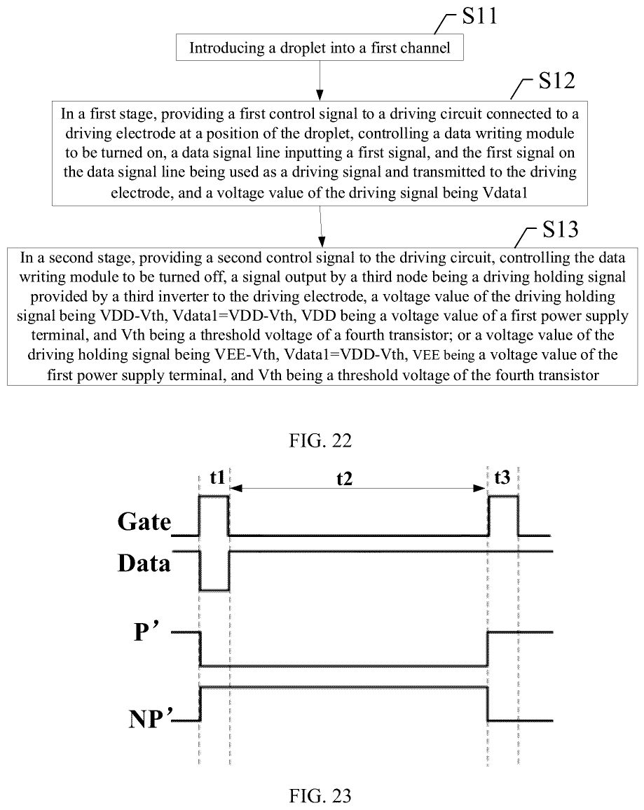

Based on a same inventive concept, the present disclosure also provides a driving method for a microfluidic driving device. FIG. 22 illustrates another flow chart of a driving method of a microfluidic driving device consistent with various embodiments of the present disclosure. FIG. 23 illustrates a timing diagram corresponding to the driving circuit in FIG. 20. In one embodiment, a corresponding driving circuit in the microfluidic driving device includes three inverters. The output terminal of the third inverter is used as the output terminal of the driving circuit. The driving method is used to drive the microfluidic driving device shown in FIG. 10. The driving method includes the following steps.

S11: introducing a droplet into the first channel 021.

S12: in a first stage t1, providing a first control signal to the driving circuit connected to a driving electrode 90 at a position of the droplet, controlling the data writing module 10 to be turned on, the data signal line Data inputting a first signal, controlling the microfluidic circuit to transmit a driving signal to the driving electrode 90, and the voltage value of the driving signal being Vdata1.

S13: in a second stage t2, providing a second control signal to the driving circuit, controlling the data writing module 10 to be turned off, providing a second control signal to the microfluidic driving circuit, controlling the data writing module 10 to be turned off, and the signal output from the third node P′ being a driving holding signal provided by the third inverter 40 to the driving electrode 90, the voltage value of the driving holding signal being VDD−Vth, Vdata1=VDD−Vth, VDD being the voltage value of the first power supply terminal D1, Vth being a threshold voltage of the transistor in the third inverter 40; or the voltage value of the driving holding signal being VEE−Vth, Vdata1=VEE−Vth, VEE being the voltage value of the first power supply terminal D1, and Vth is the threshold voltage of the transistor in the third inverter 40.

Referring to FIG. 10, FIG. 20, and FIG. 23, in one embodiment, the transistors are N-type transistors as an example for illustration. The output terminal of the third inverter 40, that is, the third node P′, is used as the output terminal of the driving circuit. In the first stage t1, the data writing module 10 is turned on, and the first signal on the data signal line Data is transmitted to the third node P′ as a driving signal and provided to the driving electrode 90 without introducing a storage capacitor, realizing fast writing of the driving signal. The voltage value of the driving signal is Vdata1. In the second stage t2, the data writing module 10 is turned off, and due to a latching effect of the three inverters, the high-level signal at the third node P′ is fed back to the gate of the fifth transistor T5 in the second inverter 30. The fifth transistor T5 is turned on, the low-level signal on the second power supply terminal D2 is transmitted to the fourth node NP′, the seventh transistor T7 is turned off, the sixth transistor T6 is turned on, and the signal on the first power supply terminal D1 is transmitted to the third node P′ through the sixth transistor T6 in the third inverter 40. A voltage value of the signal transmitted to the third node P′ is VDD−Vth. In the embodiment, VDD−Vth=Vdata1 is defined, so that the signals provided to the driving electrodes 90 in the first stage t1 and the second stage t2 are consistent, and the driving electrodes 90 can continuously and effectively drive the droplet, realizing an effective maintenance of the driving signal.

When the transistors in FIG. 20 are P-type transistors, the voltage value of the driving holding signal can be controlled to be VEE−Vth. Vdata1=VEE−Vth, VEE is the voltage value of the first power supply terminal D1, and Vth is the threshold voltage of the transistor in the third inverter 40, which is conducive to ensuring a consistency of the signal provided to the driving electrode in the first stage t1 and realizing a continuous and effective driving of the droplet.

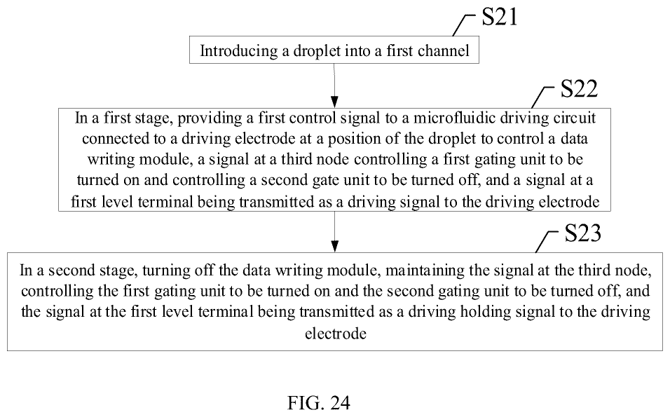

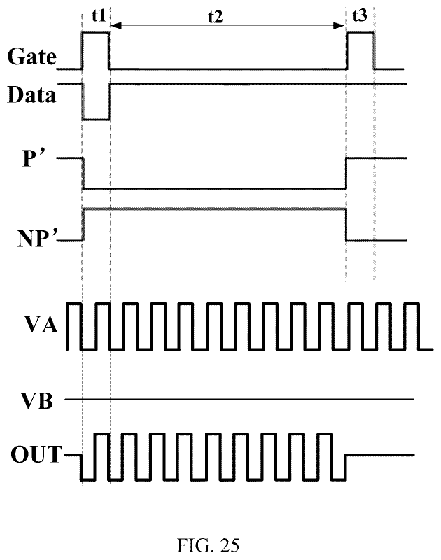

Based on a same inventive concept, the present disclosure also provides another driving method of the microfluidic driving device. FIG. 24 illustrates a flow chart of another driving method of a microfluidic driving device consistent with various embodiments of the present disclosure. The driving method is used to drive the microfluidic driving device shown in FIG. 21. Referring to FIG. 21, a microfluidic driving circuit in the microfluidic driving device also includes the gating module 80 including the first gating unit 81 and the second gating unit 82, the control terminal of the first gating unit 81 is connected to the third Node P′, the control terminal of the second gating unit 82 is connected to the fourth node NP′, the first terminal of the first gating unit 81 is connected to the first level end VA, and the second terminal of the first gating unit 81 is connected to the output end of the driving circuit. The first terminal of the second gating unit 82 is connected to the second level terminal VB, and the second terminal of the second gating unit 82 is connected to the output terminal of the driving circuit. FIG. 25 illustrates a timing diagram corresponding to the driving circuit in FIG. 24.

Referring to FIG. 21, FIG. 24 and FIG. 25, the driving method includes the following steps.

S21: introducing a droplet into the first channel 021.

S22: in a first stage t1, providing a first control signal to the microfluidic driving circuit connected to the driving electrode 90 at a position of the droplet to control the data writing module 10, a signal at the third node P′ controlling the first gating unit 81 to be turned on, the second gating unit 82 to be turned off, and a signal on the first level terminal VA being transmitted as a driving signal to the driving electrode 90.

S23: in a second stage t2, turning off the data writing module 10, maintaining the signal at the third node P′, controlling the first gating unit 81 to be turned on and the second gating unit 82 to be turned off, and the signal on the first level terminal VA being transmitted as a driving holding signal to the driving electrode 90.

In the embodiment, the driving method corresponds to the driving circuit shown in FIG. 21. The driving circuit includes three inverters and one gating module 80, the first gating unit 81 and the second gating unit 82 in the gating module 80 are controlled by the signals at the third node P′ and the fourth node NP′ respectively. In the first stage t1, when the data writing module 10 is turned on, the signal on the data signal line Data is transmitted to the third node P′ and controls the first gating unit 81 to be turned on, and the signal on the first level terminal VA is transmitted to the output terminal of the driving circuit through the first gating unit 81, and there is no need to introduce a storage capacitor, and the fast writing of the driving signal can also be realized.

In the second stage t2, the data writing module 10 is turned off, the signal at the third node P′ is maintained, the first gating unit 81 continues to be turned on, and the signal on the first level terminal VA is used as a driving holding signal. In both the first stage t1 and the second stage t2, the signal output from the first level terminal VA is used as a signal provided to the driving electrode 90, which is conducive to realizing continuous and effective driving of the droplet. Optionally, the signal on the first level terminal VA is an AC signal, which can realize the AC driving of the droplet and reduce a hysteresis effect caused by charge accumulation during the driving process.

Optionally, in the third stage t3, the data writing module 10 is turned on, and the high-level signal on the data signal line Data controls the third transistor T3 to be turned on. The low-level signal on the second power supply terminal D2 is transmitted to the third node P′, the fifth transistor T5 is turned off, the fourth transistor T4 is turned on, and the high-level signal on the first power supply terminal is transmitted to the fourth node NP′. The ninth transistor T9 is turned on, the low-level signal on the second power supply terminal D2 is transmitted to the third node P′, the tenth transistor T10 is turned off, the eleventh transistor T11 is turned on, and the DC signal on the second level terminal VB is transmitted to the output terminal OUT of the drive circuit, thereby realizing the AC drive of the droplet.

As disclosed, the driving circuit, microfluidic driving device and driving method provided by provided by the present disclosure at least realize the following beneficial effects.

In the driving circuit provided by the embodiments, one data writing module and two inverters are introduced. Two inverters form a latch circuit. When the data writing module is turned on, the data writing module writes data to the output terminal of the second inverter, and the output terminal of the second inverter can be used as the output terminal of the driving circuit. the signal can be directly provided to the driving electrode to be driven through the output terminal of the second inverter without introducing a storage capacitor and a charging process for the storage capacitor and can realize fast writing of the signal. After the data writing module is turned off, the signal from the output terminal of the second inverter is fed back to the input terminal of the first inverter to realize feedback locking of the signal, which is conducive to realizing the long-term maintenance of the signal. Therefore, the driving circuit provided by the embodiments realizes fast writing and a long-term holding of the signal, which is conducive to driving a large-scale array of driving electrode. When the driving circuit is applied to a microfluidic driving device, it is beneficial to improve the driving efficiency of droplets.

Although specific embodiments of the present disclosure have been described in detail by way of examples, a person skilled in the art should understand that the above embodiments are for illustration only, rather than limiting the scope of the present disclosure. A person skilled in the art can make modifications without departing from the scope and spirit of the present disclosure. The scope of the present disclosure is defined by the appended claims.

What is claimed is:

1. A driving circuit comprising a data writing module, a first inverter and a second inverter, wherein:
an output terminal of the data writing module is connected to a first node;
a first terminal of the first inverter is connected to a first power supply terminal, a second terminal of the first inverter is connected to a second power supply terminal, an input terminal of the first inverter is connected to the first node, and an output terminal of the first inverter is connected to a second node; and
a first terminal of the second inverter is connected to the first power supply terminal, a second terminal of the second inverter is connected to the second power supply terminal, an input terminal of the second inverter is connected to the second node, and an output terminal of the second inverter is connected to the input terminal of the first inverter.

2. The driving circuit according to claim 1, configured to provide a driving signal to a driving electrode in a microfluidic driving device, wherein:
the output terminal of the second inverter serves as an output terminal of the driving circuit and is electrically connected to the driving electrode; or
signals at the first node and the second node are configured as control signals to control a signal output at an output terminal of the driving circuit.

3. The driving circuit according to claim 1, wherein the data writing module, the first inverter and the second inverter all include transistors of a same type.

4. The driving circuit according to claim 3, wherein the data writing module includes a first transistor, a gate of the first transistor is connected to a control signal line, a first pole of the first transistor is connected to a data signal line, and a second pole of the first transistor is connected to the first node.

5. The driving circuit according to claim 3, wherein:
the first inverter includes a second transistor and a third transistor;
a gate and a first pole of the second transistor are both connected to the first power supply terminal, and a second pole of the second transistor is connected to the second node; and
a gate of the third transistor is connected to the first node, a first pole of the third transistor is connected to the second power supply terminal, and a second pole of the third transistor is connected to the second node.

6. The driving circuit according to claim 5, wherein a width-to-length ratio of the second transistor T2 is A2, a width-to-length ratio of the third transistor T3 is A3, A3=k1*A2, and k1≥10.

7. The driving circuit according to claim 3, wherein:
the second inverter includes a fourth transistor and a fifth transistor;
a gate and a first pole of the fourth transistor are both connected to the first power supply terminal, and a second pole of the fourth transistor is connected to the first node; and
a gate of the fifth transistor is connected to the second node, the first pole of the fifth transistor is connected to the second power supply terminal, and a second pole of the fifth transistor is connected to the first node.

8. The driving circuit according to claim 7, wherein a width-to-length ratio of the fourth transistor T4 is A4, a width-to-length ratio of the fifth transistor T5 is A5, A5=k3*A4, and k3≥10.

9. The driving circuit according to claim 3, wherein the transistors are all N-type transistors, the first power supply terminal is a positive power supply terminal, and the second power supply terminal is a negative power supply terminal.

10. The display panel according to claim 3, wherein the transistors are all P-type transistors, the first power supply terminal is a negative power supply terminal, and the second power supply terminal is a positive power supply terminal.

11. The driving circuit according to claim 1, further comprising a gating module, wherein:
the gating module includes a first gating unit and a second gating unit, a control terminal of the first gating unit is connected to the first node, a control terminal of the second gating unit is connected to the second node, a first terminal of the first gating unit is connected to the first level terminal, and a second end of the first gating unit is connected to the output terminal of the driving circuit; and
a first terminal of the second gating unit is connected to a second level terminal, and a second terminal of the second gating unit is connected to the output terminal of the driving circuit.

12. The driving circuit according to claim 11, wherein the first gating unit includes a sixth transistor, the second gating unit includes a seventh transistor, transistors included in the first gating unit, the second gating unit, the data writing module, the first inverter and the second inverter are of a same type.

13. The driving circuit according to claim 11, wherein:
among the first level terminal and the second level terminal, one transmits an AC signal, and the other transmits a DC signal; and
a voltage value corresponding to the AC signal is between voltage values of the first power supply terminal and the second power supply terminal.

14. A microfluidic driving device comprising a substrate, a driving layer, and a microfluidic structure layer, wherein:
the driving layer is between the substrate and the microfluidic structure layer;
the driving layer includes a driving circuit, a plurality of driving electrodes and a common electrode opposite to the driving electrodes, and an output terminal of the driving circuit is electrically connected to the plurality of driving electrodes;
the microfluidic structure layer includes at least one first channel, and the first channel corresponds to the plurality of driving electrodes, and
the driving circuit comprising a data writing module, a first inverter and a second inverter, wherein:
an output terminal of the data writing module is connected to a first node,
a first terminal of the first inverter is connected to a first power supply terminal, a second terminal of the first inverter is connected to a second power supply terminal, an input terminal of the first inverter is connected to the first node, and an output terminal of the first inverter is connected to a second node, and
a first terminal of the second inverter is connected to the first power supply terminal, a second terminal of the second inverter is connected to the second power supply terminal, an input terminal of the second inverter is connected to the second node, and an output terminal of the second inverter is connected to the input terminal of the first inverter.

15. The microfluidic driving device according to claim 14, wherein:
the driving layer includes first metal layers, active layers, and second metal layers M2 on a side of the substrate;
the first metal layers are isolated from the active layers by an insulating layer, the first metal layers are between the active layers and the substrate;
the second metal layers M2 are on a side of the active layer away from the substrate;
gates of transistors are on the first metal layers, and first poles and second poles of the transistors are on the second metal layers M2; and
an active layer includes an oxide layer or an amorphous silicon layer.

16. A driving method of the microfluidic driving device according to claim 14, comprising:
introducing a droplet into the first channel;
in a first stage, providing a first control signal to the driving circuit connected to a driving electrode at a position of the droplet, controlling the data writing module to be turned on, the data signal line inputting a first signal, and controlling the microfluidic circuit to transmit a driving signal to the driving electrode; and
in a second stage, providing a second control signal to the driving circuit, controlling the data writing module to be turned off, and the first inverter and the second inverter controlling the driving circuit to transmit a driving holding signal to the driving electrode by controlling signals at the first node and the second node.

17. A driving circuit, comprising a data writing module, a first inverter, a second inverter and a third inverter; wherein:
a first terminal of the data writing module is connected to a data signal line, a second terminal of the data writing module is connected to an input terminal of the first inverter, and a control terminal of the data writing module is connected to a control signal line;
a first terminal of the first inverter is connected to a first power supply terminal, a second terminal of the first inverter is connected to a second power supply terminal, and an output terminal of the first inverter is connected to a third node;
a first terminal of the second inverter is connected to the first power supply terminal, a second terminal of the second inverter is connected to the second power supply terminal, an input terminal of the second inverter is connected to the third node, and the output terminal of the second inverter is connected to a fourth node;
an input terminal of the third inverter is connected to the fourth node, an output terminal of the third inverter is connected to the third node, a first terminal of the third inverter is connected to the first power supply terminal, and a second terminal of the third inverter is connected to the second power supply terminal; and
the third node is used as an output terminal of the driving circuit and is electrically connected to the driving electrode; or the third node is used as a control terminal to control an output of a signal on an output terminal of the drive circuit.

18. The driving circuit according to claim 17, comprising a gating module including a first gating unit and a second gating unit, wherein:
a control terminal of the first gating unit is connected to the third node, a control terminal of the second gating unit is connected to the fourth node, and a first terminal of the first gating unit is connected to a first level terminal, a second terminal of the first gating unit is connected to an output terminal of the driving circuit.

19. The driving circuit according to claim 17, wherein the data writing module, the first inverter, the second inverter and the third inverter all include transistors of a same type.

20. A microfluidic driving device comprising a substrate, a driving layer, and a microfluidic structure layer, wherein:
the driving layer is between the substrate and the microfluidic structure layer;
the driving layer includes the driving circuit according to claim 17, a plurality of driving electrodes and a common electrode opposite to the driving electrodes, and an output terminal of the driving circuit is electrically connected to the plurality of driving electrodes; and
the microfluidic structure layer includes at least one first channel, and the first channel corresponds to the plurality of driving electrodes.
